(19) United States
(12) Patent Application Publication
(10) Pub. No.: US 2016/0133635 A1
(43) Pub. Date: May 12, 2016

(54) FLASH CELL AND FLASH CELL SET

(71) Applicant: UNITED MICROELECTRONICS CORP., Hsin-Chu City (TW)

(72) Inventor: Chang-Po Hsiung, Hsinchu City (TW)

(21) Appl. No.: 14/536,693

(22) Filed: Nov. 10, 2014

(51) Int. Cl. H01L 27/115; H01L 45/00

(52) U.S. Cl. CPC H01L 27/11521; H01L 45/146; H01L 45/144; H01L 45/1233; H01L 45/1253

(57) ABSTRACT

A flash cell includes a gate, a source/drain and a selector. The gate is disposed on a substrate, wherein the gate includes a control gate disposed on the substrate and a floating gate sandwiched by the control gate and the substrate. The source/drain is disposed in the substrate beside the gate. The selector electrically connects the source/drain, wherein the selector includes a bottom electrode, a resistance threshold switching material layer and a top electrode, and the resistance threshold switching material layer is sandwiched by the bottom electrode and the top electrode. A flash cell set includes a plurality of said flash cells. The flash cells electrically connect to each other by their selectors, and all of the selectors electrically connect to one same bit line.

### BACKGROUND OF THE INVENTION

1. Field of the Invention

The present invention relates generally to a flash cell and a flash cell set, and more specifically, to a flash cell having a selector and a flash cell set thereof.

2. Description of the Prior Art

Communication of mass information is a feature of modern life. Memory devices that access information are essential for managing such information efficiently. Flash memory, with its advantages of low power consumption, high-speed operation, being readable/writable, non-volatile, and requiring no mechanical operations, has been widely applied to personal computers and electronic apparatus. Operations of data writing, reading, and erasing can be performed repeatedly on a non-volatile memory device and the data stored therein will not be lost even when a power supply is turned off.

Flash memory includes a plurality of memory units, wherein each memory unit includes a specially made MOS (Metal-Oxide-Semiconductor) transistor. Each flash transistor includes a stacked gate having a floating gate and a control gate fabricated thereon. The control gate is disposed on the floating gate directly, the floating gate and the control gate are isolated by a dielectric layer, and the floating gate and the substrate are isolated by a tunneling oxide (this is known as a stacked gate flash memory). The flash transistor may have another selective transistor beside it, and the memory unit may be further integrated with transistors of logic units. Although the selective transistor can improve the performance of the flash memory, for example, by decreasing electrical disturbance, the presence of the selective transistor increases the size of the memory unit.

### SUMMARY OF THE INVENTION

The present invention therefore provides a flash cell and a flash cell set including a selector composed of a metal-resistance threshold switching material layer-metal structure. The aforesaid selective transistor can therefore have its functions replaced by the selector.

The present invention provides a flash cell including a gate, a source/drain and a selector. The gate is disposed on a substrate, wherein the gate includes a control gate disposed on the substrate and a floating gate sandwiched by the control gate and the substrate. The source/drain is disposed in the substrate beside the gate. The selector electrically connects the source/drain, wherein the selector includes a bottom electrode, a resistance threshold switching material layer and a top electrode, and the resistance threshold switching material layer is sandwiched by the bottom electrode and the top electrode.

The present invention provides a flash cell set including a plurality of flash cells. The flash cells electrically connect each other by their selectors, and all of the selectors electrically connect to a same bit line.

According to the above, the present invention provides a flash cell, which includes a selector besides a (flash) gate, wherein the selector is composed of a bottom electrode, a resistance switching material layer and a top electrode. A selective transistor as described in the prior art can be replaced by the selector, and the functions of the selective transistor can be reserved, thereby reducing the size of the flash cell. The selector can be integrated into current semiconductor processes, thereby simplifying processing steps and reducing processing cost. Moreover, a flash cell set including a plurality of the flash cells is provided. The flash cells connect each other by their selectors, and all of the selectors electrically connect to a same bit line. By applying a bias in a range of an operation voltage (Vop) window, a selected flash cell can be read correctly without being affected by the other un-selected flash cells.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a flash cell according to an embodiment of the present invention.

FIGS. 2-4 schematically depict cross-sectional views of a flash cell according to a first embodiment of the present invention.

FIG. 5 schematically depicts a cross-sectional view of a flash cell according to a second embodiment of the present invention.

FIG. 6 schematically depicts a cross-sectional view of a flash cell according to a third embodiment of the present invention.

FIG. 7 schematically depicts a current versus voltage curve of a selector according to an embodiment of the present invention.

FIG. 8 schematically depicts a current versus voltage curve of a flash cell including a selector according to an embodiment of the present invention.

FIG. 9 schematically depicts an operation diagram of a flash cell set according to an embodiment of the present invention.

### DETAILED DESCRIPTION

Microprocessor systems that are able to handle data and arrange information have become an important foundation of information development in our modern information society. A memory used to store digital data and to provide stored data for microprocessor systems is one of the most important structures in each kind of microprocessor system. A flash memory or an EEPROM (electrically erasable programmable read only memory), due to electron operation, is able to store data in a non-volatile way and read the stored data quickly and efficiently, unlike optical or magnetic storage media (such as a disc or an optical disc) cooperating with machines to access data. Therefore, flash memories with light volume and convenient and efficient operation have been widely utilized in various microprocessor systems, such as application chip systems, mobile phones, personal digital assistants, personal computers, and digital cameras.

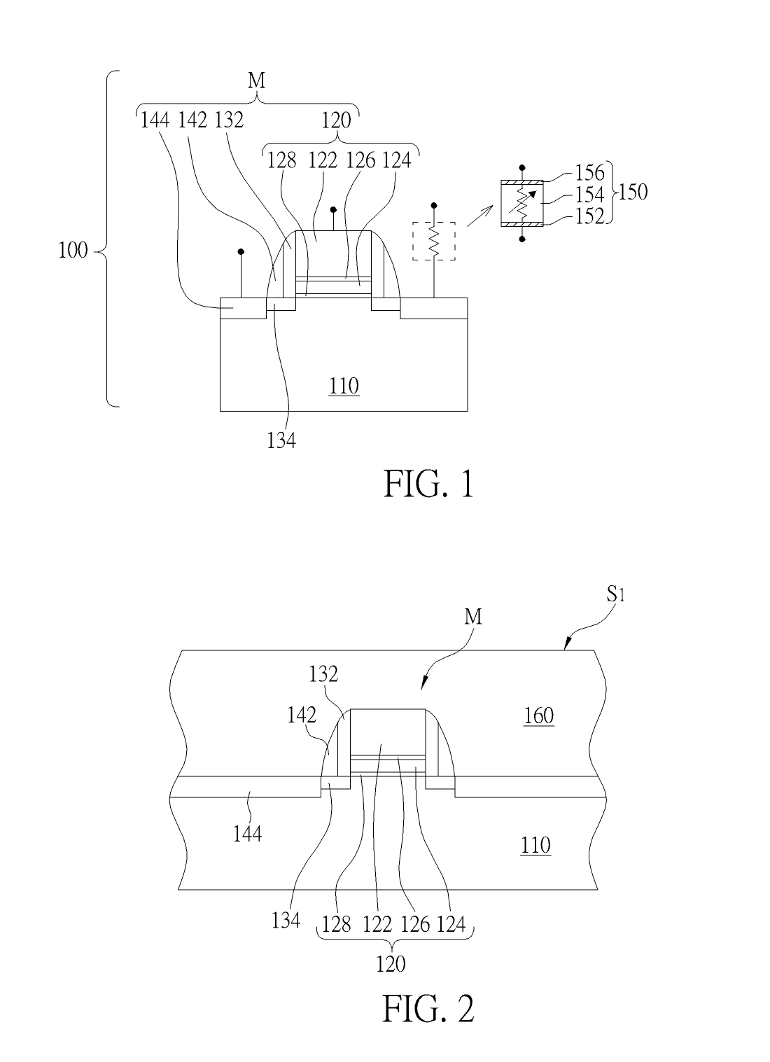

A flash cell of the present invention consists of a flash transistor including a floating gate, a control gate, and a selector connecting the flash transistor, each flash transistor serving as a memory cell for recording a bit data. FIG. 1 schematically depicts a cross-sectional view of a flash cell according to an embodiment of the present invention.

A substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. A gate 120 is formed on the substrate 110. The gate 120 is a stacked structure including a control gate 122 disposed on the substrate 110 and a floating gate 124 sandwiched by the control gate 122 and the substrate 110. A first insulating layer 126 is located between the control gate 122 and the floating gate 124 to isolate them, and a second insulating layer 128 is located between the floating gate 124 and the substrate 110 to isolate them and serve as a tunneling dielectric. An offset spacer 132 is formed on the substrate 110 beside the gate 120, and then a lightly doped source/drain 134 may be formed in the substrate 110 beside the offset spacer 132 by self-alignment. A spacer 142 is formed on the substrate 110 beside the offset spacer 132, and then a source/drain 144 is formed in the substrate 110 beside the spacer 142 by self-alignment. Thus, a flash transistor M is formed. The order of forming the lightly doped source/drain 134 and forming the source/drain 144 is not limited thereto.

While storing data, the gate G and the source/drain 144 are required to have proper bias voltages applied so that the electrons can pass through the second insulating layer 128 and flow into the floating gate 124. The amount of charge injected into the floating gate 124 will influence the threshold voltage of the flash transistor M. The more negative charge injected into the floating gate 124 of the flash transistor M, the higher the absolute value of the threshold voltage of the flash transistor M. In other words, under the circumstance of keeping the control voltage applied on the control gate 122, the bit data stored in the flash transistor M. While erasing the original data stored in the memory flash transistor M, the control gate 122 and the source/drain 144 are still required to have proper bias voltages applied, causing the electrons within the floating gate 124 to pass through the second insulating layer 128 and flow into other electrodes of the flash transistor M.

In the present invention, a selector 150 electrically connects the source/drain 144 of the flash transistor M, thereby a flash cell 100 constituted by the flash transistor M and the selector 150 is formed. The selector 150 must have a bottom electrode 152, a resistance threshold switching material layer 154 and a top electrode 156, and the resistance threshold switching material layer 154 is sandwiched by the bottom electrode 152 and the top electrode 156. When an applied bias is lower than a threshold voltage, the selector 150 cannot be turned on. When an applied bias is higher than a threshold voltage, the selector 150 is electrically operated on a breaking down section of its electrical curve, thus current can pass through the selector 150, meaning the selector 150 has a relative low resistance. As the applied bias becomes lower than a holding voltage, the selector 150 cannot keep being turned on. Hence, the selector 150 can serve as a switchable resistance through controlling an applied bias. Therefore, a selective transistor of the prior art can be replace by the selector 150. Due to the selector 150 having a simple structure which can be integrated into current semiconductor processes, the size of the flash cell 100 can be reduced.

The resistance switching material layer 154 may include polysilicon, vanadium oxide (VO₂), hafnium oxide (HfO₂), titanium oxide (TiO₂), copper oxide (CuO), or silicon (Si)-arsenic (As)-tellurium (Te) compounds to have a practical holding voltage and a practical threshold voltage for switching while the bottom electrode 152 and the top electrode 156 may include titanium nitride (TiN), tantalum nitride (TaN), platinum (Pt), aluminum (Al), tungsten (W), copper (Cu) and ruthenium (Ru), but this is not limited thereto.

According to the above, the flash cell 100 of the present invention includes a flash transistor M and a selector 150 electrically connecting to the source/drain 144 of the flash transistor M. There are many ways to electrically connect selector 150 to the source/drain 144 of the flash transistor M as well as integrate the selector 150 into current semiconductor processes. Three embodiments are presented as follows, but the present invention is not restricted thereto.

FIGS. 2-4 schematically depict cross-sectional views of a flash cell according to a first embodiment of the present invention. As shown in FIG. 2, a flash transistor M the same as that shown in FIG. 1 is provided. A gate 120 is located on a substrate 110. The gate 120 includes a control gate 122 disposed on the substrate 110 and a floating gate 124 sandwiched by the control gate 122 and the substrate 110. The gate 120 further includes a first insulating layer 126 between the control gate 122 and the floating gate 124, and a second insulating layer 128 between the floating gate 124 and the substrate 110. An offset spacer 132 is on the substrate 110 beside the gate 120, and a lightly doped source/drain 134 is in the substrate 110 beside the offset spacer 132. A spacer 142 is on the substrate 110 beside the offset spacer 132, and a source/drain 144 is in the substrate 110 beside the spacer 142.

Thereafter, a first dielectric layer 160 covers the gate 120 and the source/drain 144. Precisely, a first dielectric layer (not shown) may be deposited to blanketly cover the gate 120 and the substrate 110, and then the first dielectric layer is planarized to form the first dielectric layer 160 having a flat top surface S1. In this embodiment, the first dielectric layer 160 is an interdielectric (ILD) layer, which may be composed of oxide, but is not limited thereto.

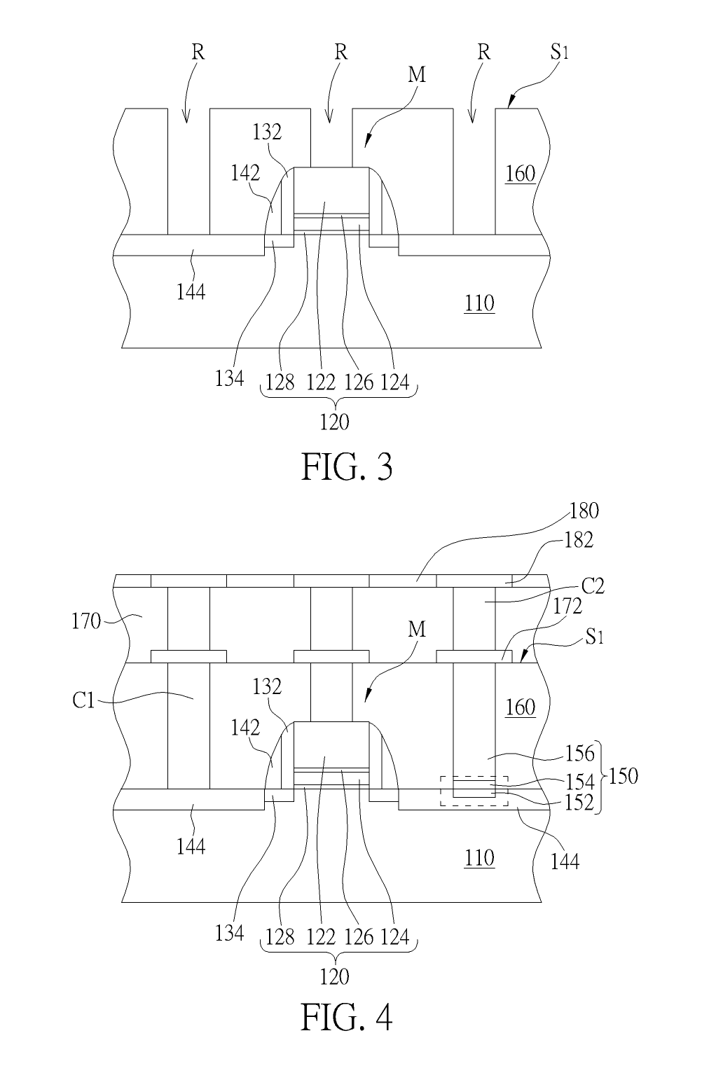

The first dielectric layer 160 is then etched to expose a part of the source/drain 144 and the gate 120, to form first contact holes R, as shown in FIG. 3. In this embodiment, only a part of the source/drain 144 is exposed; in another embodiment, the whole source/drain 144 may be exposed. Then, as shown in FIG. 4, a selector 150 of FIG. 1 including a bottom electrode 152, a resistance switching material layer 154 and a top electrode 156 is formed in one of the first contact holes R. In this embodiment, the bottom part 152 may be a metal silicide formed by performing a salicide process on the exposed part of the source/drain 144, so that the metal silicide is only located in the exposed part of the source/drain 144, but this is not limited thereto. In another embodiment, the metal silicide may be formed by performing a salicide process immediately before the first dielectric layer 160 is formed, so that the metal silicide is located in the whole upper part of the source/drain 144. Then, the resistance threshold switching material layer 154 is formed on and contacts the bottom electrode 152. The resistance threshold switching material layer 154 may include polysilicon, vanadium oxide (VO₂), hafnium oxide (HfO₂), titanium oxide (TiO₂), copper oxide (CuO), or silicon (Si)-arsenic (As)-tellurium (Te) compounds, which may be formed by chemical vapor deposition (CVD) process, but this is not limited thereto. The top electrode 156 is then formed on the resistance threshold switching material layer 154, which is one of the first contact plugs C1 formed in the first contact holes R by filling a metal such as copper.

In this embodiment, the bottom part 152 is a metal silicide while the top electrode 156 is a first contact plug, so the selector 150 of the present invention can be integrated into current processes well by only forming an extra resistance threshold switching material layer 154. This simplifies the processing step, reduces processing cost and saves processing time. In other cases, at least one of the bottom part 152 and the top electrode 156 may be formed in the first contact hole R for better structural or property considerations, depending upon practical requirements. In this embodiment, the selector 150 directly connects the source/drain 144 and is sandwiched by the source/drain 144 and the first contact plug 152.

Thereafter, a second dielectric layer 170 may covers the first dielectric layer 160 and the first contact plugs C1. In this embodiment, the second dielectric layer 170 is an inter-metal dielectric (IMD) layer, but is not limited thereto. The second dielectric layer 170 has an interconnect stricture 172 and second contact plugs C2 therein. Methods of forming the interconnect stricture 172 and the second contact plugs C2 are known in the art, and are not described herein. Thereafter, other semiconductor processes may be performed such as forming a third dielectric layer 180, which has an interconnect stricture 182 therein, to cover the second dielectric layer 170.

The selector 150 is formed in the first dielectric layer 160 in this embodiment; however, the selector 150 of the present invention may be formed in other layers. Two embodiments are presented as follows, which form the selector 150 of the present invention in the second dielectric layer meaning the inter-metal dielectric (IMD) layer, but the present invention is not restricted thereto.

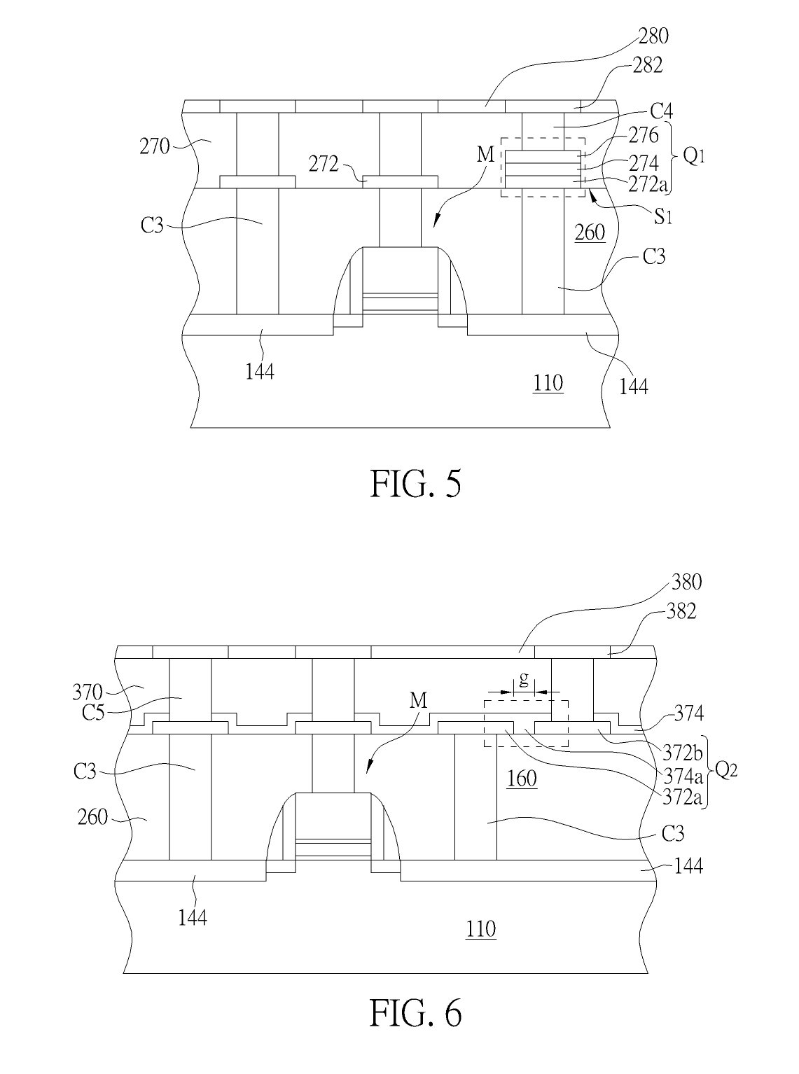

FIG. 5 schematically depicts a cross-sectional view of a flash cell according to a second embodiment of the present invention. In this embodiment, the structure of the flash transistor M is the same as that of the first embodiment, except that first contact plugs C3 are directly formed in the first dielectric layer 260 without first forming the selector 150. Methods of forming the first dielectric layer 260 and the first contact plugs C3 are similar to that of the first embodiment.

As shown in FIG. 5, a second dielectric layer 270 covers the first dielectric layer 260 and the first contact plugs C3. The second dielectric layer 270 not only has an interconnect stricture 272 and second contact plugs C4 but also has a selector Q1 of the present invention therein. More precisely, the interconnect stricture 272 may be formed by metals such as aluminum deposited and patterned to directly contact the first contact plugs C3, wherein one of the interconnect stricture serves as a bottom electrode 272a of the selector Q1. Then, a resistance switching material layer 274 and a top electrode 276 of the selector Q1 may be formed sequentially to directly contact the bottom electrode 272a. This means the selector Q1 is formed completely. Thereafter, a second dielectric layer (not shown) is deposited and etched to expose the interconnect structure 272 and the top electrode 276, and the second contact plugs C4 are formed to directly contact the interconnect stricture 272 and the top electrode 276 by methods such as filling metals. Thereafter, other semiconductor processes may be performed such as forming a third dielectric layer 280, which has an interconnect structure 282 therein and covers the second dielectric layer 270.

In this embodiment, the selector Q1 is disposed in the second dielectric layer 270 and on the first contact plug C3 to connect the source/drain 144 through one of the first contact plugs C3.

In the first and the second embodiment, the selector Q1 includes the bottom electrode 152/272a, the resistance threshold switching material layer 154/274 and the top electrode 156/276 stacked from bottom to top. A third embodiment is presented in the following, which has a selector including a bottom electrode, a resistance threshold switching material layer and a top electrode arranged side by side.

FIG. 6 schematically depicts a cross-sectional view of a flash cell according to a third embodiment of the present invention. The structure of this embodiment is similar to the structure of the second embodiment as shown in FIG. 5. The difference is that a selector Q2 in a second dielectric layer 370 includes a bottom electrode 372a, a resistance threshold switching material layer 374a and a top electrode 372b. The bottom electrode 372a and the top electrode 372b are in a same level. The resistance threshold switching material layer 374a is in a gap g between the bottom electrode 372a and the top electrode 372b.

More precisely, after the first dielectric layer 260 having the first contact plug C3 therein covering the flash transistor M as described in the second embodiment, an interconnect structure 372 may be formed by metals such as aluminum deposited and patterned to directly contact the first contact plugs C3 and on the first dielectric layer 260. Then, the resistance threshold switching material layer 374 conformally covers the interconnect structure 372 and the first dielectric layer 260. Thereafter, a second dielectric layer (not shown) is deposited and etched to form the second contact plugs C5 in the second dielectric layer 370. In this embodiment, one part of the interconnect structure 372 serves as the bottom electrode 372a of the selector Q2 while another part of the interconnect structure 372 serves as the top electrode 372b of the selector Q2. The gap g is between the bottom electrode 372a and the top electrode 372b. Apart of the resistance threshold switching material layer 374 in the gap g serves as the resistance threshold switching material layer 374a of the selector Q2. Therefore, one of the first contact plugs C3 contacting the bottom electrode 372a and one of the second contact plugs C5 contacting the top electrode 372b are dislocated.

Thereafter, other semiconductor processes may be performed such as forming a third dielectric layer 380, which has an interconnect structure 382 therein and covers the second dielectric layer 370.

These three embodiments are provided to describe three ways of electrically connecting a selector to a flash transistor to constitute a flash cell of the present invention.

The operation of the flash cell of the present invention is illustrated in the following.

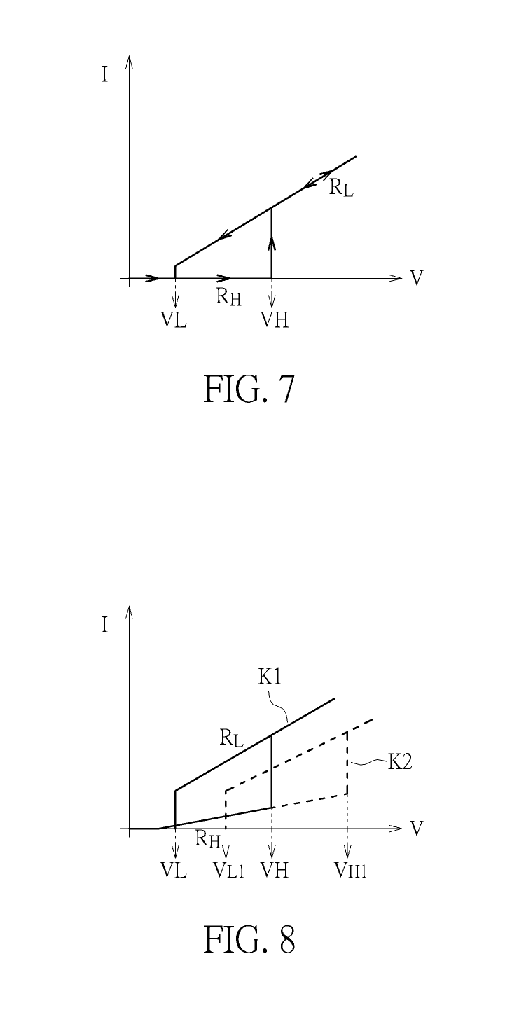

FIG. 7 schematically depicts a current versus voltage curve of a selector according to an embodiment of the present invention. A selector of the present invention has the electrical I-V curve shown in FIG. 7. This means the selector can be seen as turned off when an applied bias V is lower than a threshold voltage (VH) because of a high initial resistance (RH), and the selector can be turned on when an applied bias V is larger than the threshold voltage (VH). As the selector is turned on, the selector has a low resistance (RL), which is much lower than the high initial resistance (RH). It is noted that the selector can keep being turned on with the low resistance (RL) as the applied bias is larger than a holding voltage (VL). Therefore, the selector can work as a switchable resistor.

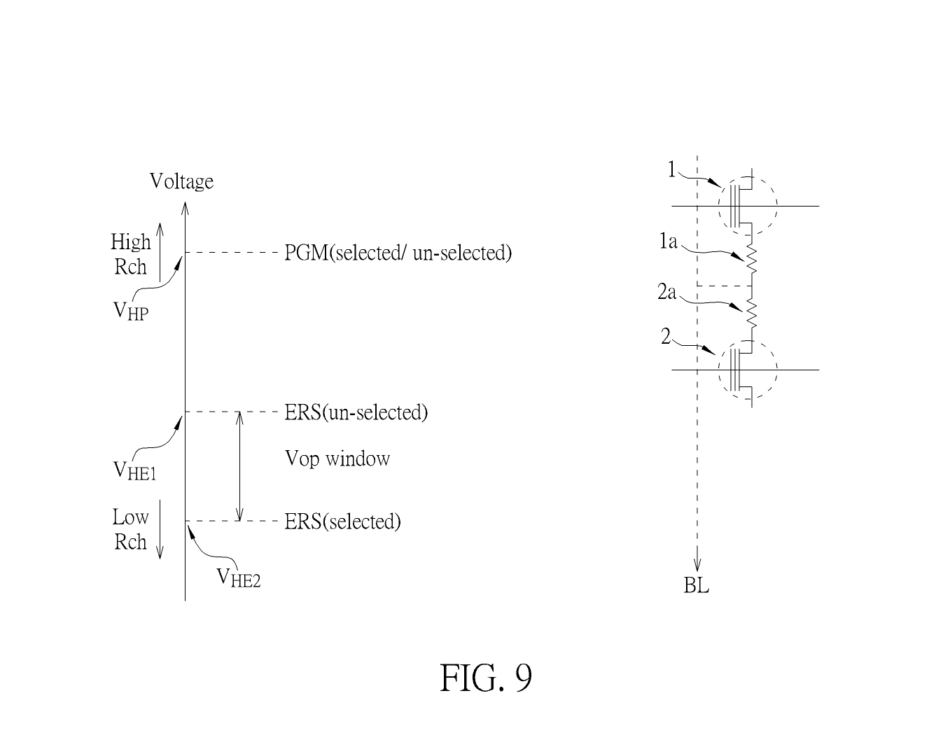

FIG. 8 schematically depicts a current versus voltage curve of a flash cell including a selector according to an embodiment of the present invention. As the above selector is connected to a flash transistor to constitute a flash cell, the flash cell has the electrical I-V curve shown in FIG. 8 due to a channel resistance (Rch) of the flash transistor. As the channel resistance (Rch) is much lower than the high initial resistance (RH), the electrical curve K1 is similar to that of said pure selector, i.e. the threshold voltage (VH) and the holding voltage (VL) are almost the same as the pure selector. As the channel resistance (Rch) is larger than the high initial resistance (RH), anew threshold voltage (VH1) is larger than the threshold voltage (VH) and a new holding voltage (VL1) is larger than the holding voltage (VL). The new threshold voltage (VH1) depends upon the channel resistance (Rch). As the channel resistance (Rch) becomes higher, the new threshold voltage (VH1) becomes higher as well.

FIG. 9 schematically depicts an operation diagram of a flash cell set according to an embodiment of the present invention. As a flash cell 1 of the present invention and a flash cell 2 of the present invention connect to each other by their selectors 1a/2a, and both of the selectors 1a/2a electrically connect to one same bit line BL, an operating voltage (Vop) window can be obtained as the flash cell 1 is selected to be read while the flash cell 2 is not selected to be read. That is, while an applied bias falls in the range of the operating voltage (Vop) window, the selected flash cell 1 can be read correctly without being affected by the un-selected flash cell 2.

In detail, the channel resistance (Rch) of the un-selected flash cell 2 on erase state (ERS) is adjusted to be higher than the channel resistance (Rch) of the selected flash cell 1 in an erase state (ERS) through an applied voltage to the control gates of the flash cell 1 and the flash cell 2. As the flash cell 1 and the flash cell 2 are both in programming mode (PGM), both the flash cell 1 and the flash cell 2 have high channel resistance (Rch), leading to both the flash cell 1 and the flash cell 2 having high threshold voltage (VHP). Hence, the flash cell 1 and the flash cell 2 will be turned off while an applied bias is in the range of the operating voltage (Vop) window. As a result, the selected flash cell 1 can be read as in programming mode.

In another situation, if the flash cell 1 is in a programming mode while the flash cell 2 is in an erase state (ERS), the flash cell 1 has high channel resistance (Rch) while the flash cell 2 has sub-high channel resistance (Rch), leading to the flash cell 1 having a high threshold voltage (VHP) while the flash cell 2 has a sub-high threshold voltage (VHE1) higher than the range of the operating voltage (Vop) window. Hence, the flash cell 1 and the flash cell 2 will be turned off while an applied bias is in the range of the operating voltage (Vop) window. As a result, the selected flash cell 1 can be read as in programming mode.

In another situation, if the flash cell 1 is in an erase state while the flash cell 2 is in programming mode, the flash cell 1 has low channel resistance (Rch) while the flash cell 2 has high channel resistance (Rch), leading to the flash cell 1 having a low threshold voltage (VHE2) lower than the range of the operating voltage (Vop) window while the flash cell 2 has a high threshold voltage (VHP) higher than the range of the operating voltage (Vop) window. Hence, the flash cell 1 is turned on while the flash cell 2 is turned off as an applied bias is in the range of the operating voltage (Vop) window. As a result, the selected flash cell 1 can be read as in an erase state.

In another situation, if the flash cell 1 as well as the flash cell 2 are both in an erase state, the flash cell 1 has low channel resistance (Rch) while the flash cell 2 has sub-high channel resistance (Rch), leading to the flash cell 1 having a low threshold voltage (VHE2) lower than the range of the operating voltage (Vop) window while the flash cell 2 has a sub-high threshold voltage (VHE1) higher than the range of the operating voltage (Vop) window. Hence, the flash cell 1 is turned on while the flash cell 2 is turned off as an applied bias is in the range of the operating voltage (Vop) window. As a result, the selected flash cell 1 can be read as in an erase state.

According to the above, the selected flash cell 1 can be read correctly without being affected by the state of the un-selected flash cell 2. In this embodiment, only two flash cells are depicted, but the number of the flash cells is not limited thereto.

To summarize, the present invention provides a flash cell, which includes a selector besides a flash transistor, wherein the selector is composed a bottom electrode, a resistance threshold switching material layer and a top electrode. A selective transistor as taught by the prior art can be replaced by the selector, and the functions of the selective transistor can be reserved, to reduce the size of the flash cell. The selector can be integrated into current semiconductor processes, thereby simplifying processing steps and reducing processing cost. Moreover, a flash cell set including a plurality of the flash cells is provided. The flash cells connect to each other by their selectors, and all of the selectors electrically connect to one same bit line. By applying a bias in a range of an operation voltage (Vop) window, a selected flash cell can be read correctly without being affected by the other un-selected flash cells.

More precisely, the resistance threshold switching material layer may include polysilicon, vanadium oxide (VO₂), hafnium oxide (HfO₂), titanium oxide (TiO₂), copper oxide (CuO), or silicon (Si)-arsenic (As)-tellurium (Te) compounds; the bottom electrode and the top electrode may include titanium nitride (TiN), tantalum nitride (TaN), platinum (Pt), aluminum (Al), tungsten (W), copper (Cu) and ruthenium (Ru), but this is not limited thereto. The selector may be formed on an interdielectric layer or an inter-metal dielectric (IMD) layer. The selector may have the bottom electrode, the resistance threshold switching material layer and the top electrode stacked from bottom to top, or may have the bottom electrode, the resistance threshold switching material layer and the top electrode arranged side by side.

Those skilled in the art will readily observe that numerous modifications and alterations of the device and method may be made while retaining the teachings of the invention. Accordingly, the above disclosure should be construed as limited only by the metes and bounds of the appended claims.

1. A flash cell, comprising:
a gate disposed on a substrate, wherein the gate comprises a control gate disposed on the substrate and a floating gate sandwiched by the control gate and the substrate;
a source/drain disposed in the substrate beside the gate; and
a selector electrically connecting the source/drain and only disposed in a first dielectric layer physically contacting the substrate, wherein the selector comprises a bottom electrode, a resistance threshold switching material layer and a top electrode, and the resistance threshold switching material layer is sandwiched by the bottom electrode and the top electrode.

2. The flash cell according to claim 1, wherein the resistance threshold switching material layer comprises polysilicon, vanadium oxide (VO2), hafnium oxide (HfO2), titanium oxide (TiO2), copper oxide (CuO), or silicon (Si)-arsenic (As)-tellurium (Te) compounds.

3. The flash cell according to claim 1, wherein the bottom electrode and the top electrode comprise titanium nitride (TiN), tantalum nitride (TaN), platinum (Pt), aluminum (Al), tungsten (W), copper (Cu) and ruthenium (Ru).

4. The flash cell according to claim 1, wherein the first dielectric layer covers the gate and the source/drain.

5. The flash cell according to claim 4, wherein the first dielectric layer comprises an interdielectric layer.

6. The flash cell according to claim 1, further comprising:
a spacer on the substrate beside the gate.

7. The flash cell according to claim 4, wherein the first dielectric layer has a first contact hole to expose at least a part of the source/drain.

8. The flash cell according to claim 7, further comprising:
a first contact plug filling at least a part of the first contact hole.

9. The flash cell according to claim 8, wherein the selector is disposed in the first contact hole.

10. The flash cell according to claim 9, wherein the selector directly connects the source/drain and is sandwiched by the source/drain and the first contact plug.

11. The flash cell according to claim 8, wherein the selector connects the source/drain through the first contact plug.

12. The flash cell according to claim 8, wherein the selector is disposed on the first contact plug.

13. The flash cell according to claim 4, further comprising:
a second dielectric layer covering the first dielectric layer.

14. The flash cell according to claim 13, wherein the second dielectric layer comprises an inter-metal dielectric (IMD) layer.

15. The flash cell according to claim 13, wherein the selector is disposed in the second dielectric layer.

16. The flash cell according to claim 1, wherein the bottom electrode, the resistance threshold switching material layer and the top electrode are stacked from bottom to top.

17. The flash cell according to claim 1, wherein the bottom electrode, the resistance threshold switching material layer and the top electrode are arranged side by side.

18. The flash cell according to claim 1, wherein the bottom electrode and the top electrode are disposed in a same level with a gap between them, and the resistance threshold switching material layer disposed in the gap.

19. The flash cell according to claim 18, wherein the resistance threshold switching material layer covers the bottom electrode, the gap and the top electrode.

20. A flash cell set, further comprising:
a plurality of the flash cells according to claim 1 electrically connecting to each other by their selectors, wherein all of the selectors electrically connect to one same bit line.
